(19) United States
(12) Patent Application Publication
(10) Pub. No.: US 2023/0155346 A1
(43) Pub. Date: May 18, 2023

(54) SEMICONDUCTOR LIGHT EMITTING DEVICE

(71) Applicant: Panasonic Holdings Corporation, Osaka (JP)

(72) Inventor: Shinichiro NOZAKI, Osaka (JP)

(21) Appl. No.: 18/098,825

(22) Filed: Jan. 19, 2023

Related U.S. Application Data
(63) Continuation of application No. PCT/JP2021/023768, filed on Jun. 23, 2021.

(30) Foreign Application Priority Data
Aug. 4, 2020 (JP) 2020-132661

(51) Int. Cl. H01S 5/023; H01S 5/042; H01S 5/0237

(52) U.S. Cl. CPC H01S 5/023; H01S 5/04256; H01S 5/0237

(57) ABSTRACT

Semiconductor light emitting device includes semiconductor light emitting element and submount that includes mounting surface, semiconductor light emitting element includes: semiconductor multilayer structure that includes opposite surface opposite mounting surface and emission surface; and mounting electrode that is arranged on opposite surface and extends in a direction of emission of light, emission surface is located outside of an end portion of mounting surface, groove is formed in opposite surface of semiconductor multilayer structure to extend along mounting electrode in the direction of emission, and a first distance between emission surface and groove is greater than zero and less than a second distance between emission surface and mounting surface.

### CROSS REFERENCE TO RELATED APPLICATIONS

This is a continuation application of PCT International Application No. PCT/JP2021/023768 filed on Jun. 23, 2021, designating the United States of America, which is based on and claims priority of Japanese Patent Application No. 2020-132661 filed on Aug. 4, 2020. The entire disclosures of the above-identified applications, including the specifications, drawings and claims are incorporated herein by reference in their entirety.

### FIELD

The present disclosure relates to semiconductor light emitting devices.

### BACKGROUND

Conventionally, light such as laser light is used for processing applications, and thus light sources having a high output and high efficiency are required. As the light sources having a high output and high efficiency, semiconductor light emitting devices are utilized. For example, the high-output semiconductor light emitting device as described above includes a semiconductor light emitting element such as a semiconductor laser element and a submount on which the semiconductor light emitting element is mounted. In the semiconductor light emitting device as described above, the semiconductor light emitting element is mounted on the submount using a bonding material such as a solder. When the semiconductor light emitting element is mounted on the submount, the solder may flow out from between an emission surface from which the light of the semiconductor light emitting element is emitted and the submount. The solder which has flowed out as described above hardens in a state where the solder protrudes in the vicinity of the emission surface of the semiconductor light emitting element, and thus the solder blocks the light from the semiconductor light emitting element and interferes with an optical element arranged in the vicinity of the emission surface of the semiconductor light emitting element.

A conventional technique for solving such a problem will be described with reference to FIGS. 13A and 13B. FIG. 13A is a schematic cross-sectional view showing the configuration of a semiconductor light emitting device disclosed in Patent Literature (PTL) 1. FIG. 13B is a schematic perspective view showing the configuration of submount 1020 disclosed in PTL 1. As shown in FIG. 13A, the semiconductor light emitting device disclosed in PTL 1 includes submount 1020 and semiconductor laser element 1001 which is mounted via solder 1006. Submount 1020 is arranged on heatsink 1003. As shown in FIGS. 13A and 13B, guide portions 1021 are formed in end surfaces 1020a and 1020b of submount 1020 formed of AlN (aluminum nitride). Guide portions 1021 are parts formed by embedding, in recessed portions formed in submount 1020, Pt which has better wettability to solder 1006 than submount 1020. The emission surface of the semiconductor light emitting element is arranged in the vicinity of guide portions 1021. In this way, solder 1006 is spread thinly over the surfaces of guide portions 1021, and thus an attempt is made to suppress the protrusion of solder 1006 in the vicinity of the emission surface of semiconductor laser element 1001.

### CITATION LIST

### Patent Literature

PTL 1: Japanese Unexamined Patent Application Publication No. 2003-324228

### SUMMARY

### Technical Problem

In semiconductor laser element 1001 disclosed in PTL 1, a part in the vicinity of the emission surface is the hottest part. On the other hand, Pt arranged in guide portions 1021 has lower thermal conductivity than AlN. Hence, Pt is embedded in submount 1020, and thus heat dissipation properties in the vicinity of the emission surface of semiconductor laser element 1001 are degraded. Therefore, when high-output semiconductor laser element 1001 is used, a catastrophic optical damage (COD) may occur in the vicinity of the emission surface of semiconductor laser element 1001.

The present disclosure is made to solve the problem as described above, and an object thereof is to provide a semiconductor light emitting device which has satisfactory heat dissipation properties and can suppress the protrusion of a bonding material in the vicinity of the emission surface of a semiconductor light emitting element.

### Solution to Problem

In order to solve the problem described above, an aspect of a semiconductor light emitting device according to the present disclosure is a semiconductor light emitting device that includes: a semiconductor light emitting element that emits light; and a submount that includes a mounting surface on which the semiconductor light emitting element is mounted via a bonding material, the semiconductor light emitting element includes: a semiconductor multilayer structure that includes: an opposite surface opposite the mounting surface; and an emission surface which is located at an end portion of the opposite surface and emits the light; and one or more mounting electrodes that are arranged on the opposite surface of the semiconductor multilayer structure and extend in a direction of emission of the light, the emission surface is located outside of an end portion of the mounting surface, one or more grooves are formed in the opposite surface of the semiconductor multilayer structure to extend along the one or more mounting electrodes in the direction of emission, and a first distance between the emission surface and the one or more grooves is greater than zero and less than a second distance between the emission surface and the mounting surface.

In this way, the bonding material can be guided into the grooves, and thus it is possible to reduce the amount of bonding material which flows out from between the semiconductor light emitting element and the submount. By a relative relationship between the first distance, the second distance, and a third distance, the bonding material flowing out from between the semiconductor light emitting element and the submount via the groove is guided to flow along the side wall of the groove which is substantially parallel to the emission surface. In other words, the bonding material is guided to flow along an end surface located at the end portion of the mounting surface of the submount. Hence, it is possible to suppress the protrusion of the bonding material in a direction perpendicular to the emission surface in the vicinity of the emission surface. Since the mounting electrode in the vicinity of the emission surface is bonded to the submount, the heat dissipation properties of the semiconductor light emitting device in the vicinity of the emission surface are not degraded.

In the aspect of the semiconductor light emitting device according to the present disclosure, the second distance may be less than a third distance between the emission surface and the one or more mounting electrodes.

As described above, the second distance is less than the third distance, and thus heat generated in the vicinity of the end portion of the mounting electrode of the semiconductor light emitting element close to the emission surface is dissipated not only in the direction perpendicular to the mounting surface but also in a direction toward the end surface of the submount, that is, in a direction inclined with respect to the mounting surface. Hence, it is possible to enhance the heat dissipation properties of semiconductor light emitting device 101.

In the aspect of the semiconductor light emitting device according to the present disclosure, the semiconductor multilayer structure may include: a substrate; a first semiconductor layer of a first conductivity type arranged above the substrate; a light emitting layer arranged above the first semiconductor layer; and a second semiconductor layer of a second conductivity type different from the first conductivity type, the second semiconductor layer being arranged above the light emitting layer, and the one or more mounting electrodes may be arranged above the second semiconductor layer.

In this case, the semiconductor light emitting element is junction-down mounted. In this way, as compared with a case where the semiconductor light emitting element is junction-up mounted, the light emitting layer which generates a large amount of heat can be arranged close to the submount, and thus it is possible to enhance the heat dissipation properties of the semiconductor light emitting device.

In the aspect of the semiconductor light emitting device according to the present disclosure, the one or more mounting electrodes may include a first mounting electrode, the one or more grooves may include a first groove adjacent to the first mounting electrode, and an average distance in a direction perpendicular to the direction of emission between the first mounting electrode and a part of the first groove adjacent to the first mounting electrode in the direction perpendicular to the direction of emission may be less than an average distance in the direction perpendicular to the direction of emission between the first mounting electrode and a part of the first groove located closer to the emission surface than the first mounting electrode.

As described above, the groove is formed in the vicinity of the light emitting layer, and thus a bandgap in the light emitting layer is decreased. As a distance between the light emitting layer and the groove is smaller, the bandgap in the light emitting layer is decreased. Hence, a distance up to the groove in a non-injection region which extends from the mounting electrode to the groove and into which current is not injected is increased as compared with a distance from the mounting electrode to the groove, and thus the bandgap in the light emitting layer in the non-injection region can be increased as compared with the bandgap in the light emitting layer in an injection region into which current is injected by the mounting electrode. Therefore, it is possible to reduce light absorption in the light emitting layer in the non-injection region. In this way, the amount of heat generated in the non-injection region can be reduced, with the result that the occurrence of a COD can be suppressed.

In the aspect of the semiconductor light emitting device according to the present disclosure, a side wall of each of the one or more grooves may include a layer that has higher wettability to the bonding material than the semiconductor multilayer structure.

In this way, the wettability of the side walls of the grooves can be enhanced, and thus it is possible to enhance an effect of guiding the bonding material into the grooves.

In the aspect of the semiconductor light emitting device according to the present disclosure, the side wall of each of the one or more grooves may include an Au layer.

In this way, the wettability of the side walls of the grooves can be enhanced, and thus it is possible to enhance the effect of guiding the bonding material into the grooves.

In the aspect of the semiconductor light emitting device according to the present disclosure, in each of the one or more grooves, one or more projecting portions may be formed.

In this way, the area of the front surface having high wettability can be enhanced, and thus it is possible to enhance the effect of guiding the bonding material into the grooves.

In the aspect of the semiconductor light emitting device according to the present disclosure, the one or more mounting electrodes may include a plurality of mounting electrodes, and the one or more grooves may include a plurality of grooves.

When as described above, the semiconductor light emitting element is a multi-emitter type, though the amount of heat generated in the semiconductor light emitting element is further increased, the heat dissipation properties caused by the submount are satisfactory, with the result that it is possible to suppress the occurrence of a COD.

### Advantageous Effects

According to the present disclosure, it is possible to provide a semiconductor light emitting device which has satisfactory heat dissipation properties and can suppress the protrusion of a bonding material in the vicinity of the emission surface of a semiconductor light emitting element.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 is a schematic perspective view showing the overall configuration of a semiconductor light emitting element in Embodiment 1.

FIG. 2 is a schematic perspective view showing the overall configuration of a semiconductor light emitting device according to Embodiment 1.

FIG. 3 is a schematic plan view showing a configuration in the vicinity of the emission surface of the semiconductor light emitting device according to Embodiment 1.

FIG. 4 is a schematic first cross-sectional view showing the configuration of the semiconductor light emitting device according to Embodiment 1.

FIG. 5 is a schematic second cross-sectional view showing the configuration of the semiconductor light emitting device according to Embodiment 1.

FIG. 6 is a schematic third cross-sectional view showing the configuration of the semiconductor light emitting device according to Embodiment 1.

FIG. 7 is a schematic first cross-sectional view illustrating the action of the semiconductor light emitting device according to Embodiment 1.

FIG. 8 is a schematic second cross-sectional view illustrating the action of the semiconductor light emitting device according to Embodiment 1.

FIG. 9 is a schematic plan view showing a configuration in the vicinity of the emission surface of a semiconductor light emitting element included in a semiconductor light emitting device according to Embodiment 2.

FIG. 10 is a schematic plan view showing a configuration in the vicinity of the emission surface of a semiconductor light emitting element included in a semiconductor light emitting device according to Embodiment 3.

FIG. 11 is a schematic plan view showing a configuration in the vicinity of the emission surface of a semiconductor light emitting device according to Embodiment 4.

FIG. 12 is a schematic cross-sectional view showing a configuration in the vicinity of the emission surface of the semiconductor light emitting device according to Embodiment 4.

FIG. 13A is a schematic cross-sectional view showing the configuration of a semiconductor light emitting device disclosed in PTL 1.

FIG. 13B is a schematic perspective view showing the configuration of a submount disclosed in PTL 1.

### DESCRIPTION OF EMBODIMENTS

Embodiments of the present disclosure will be described below with reference to drawings. Each of the embodiments described below shows a specific example of the present disclosure. Hence, values, shapes, materials, constituent elements, the arrangements, positions, and connection forms of the constituent elements, and the like which are shown in the embodiments below are examples, and are not intended to limit the present disclosure.

The drawings each are schematic views, and are not exactly shown. Hence, in the drawings, scales and the like are not necessarily the same as each other. In the drawings, substantially the same configurations are identified with the same reference signs, and the repeated description thereof is omitted or simplified.

In the present specification, the terms “upward” and “downward” do not indicate an upward direction (vertically upward) and a downward direction (vertically downward) in absolute spatial recognition but are used as terms specified by a relative positional relationship based on a stacking order in a stacking configuration. The terms “upward” and “downward” are applied not only to a case where two constituent elements are spaced with another constituent element present between the two constituent elements but also to a case where two constituent elements are arranged in contact with each other.

### Embodiment 1

A semiconductor light emitting device according to Embodiment 1 will be described.

### [1-1. Overall Configuration]

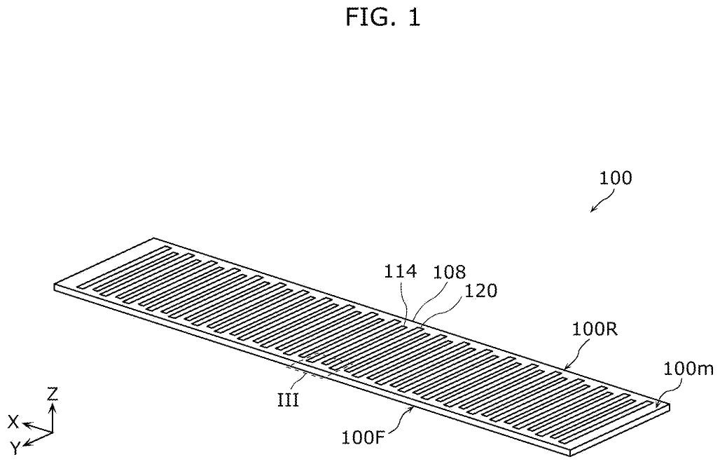

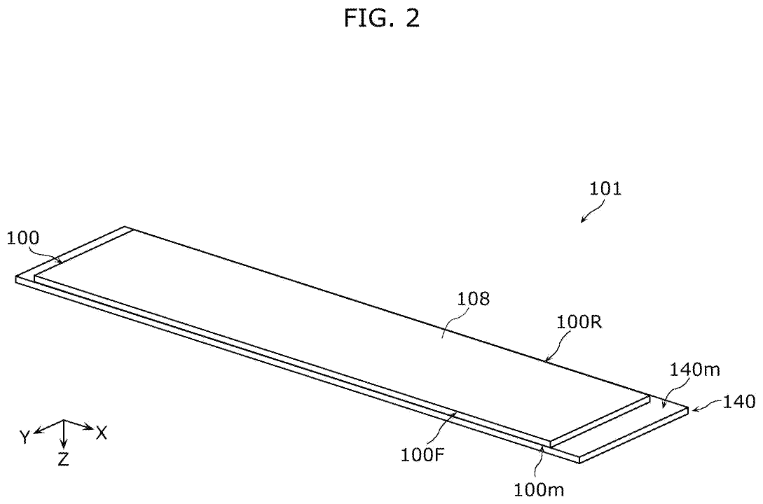

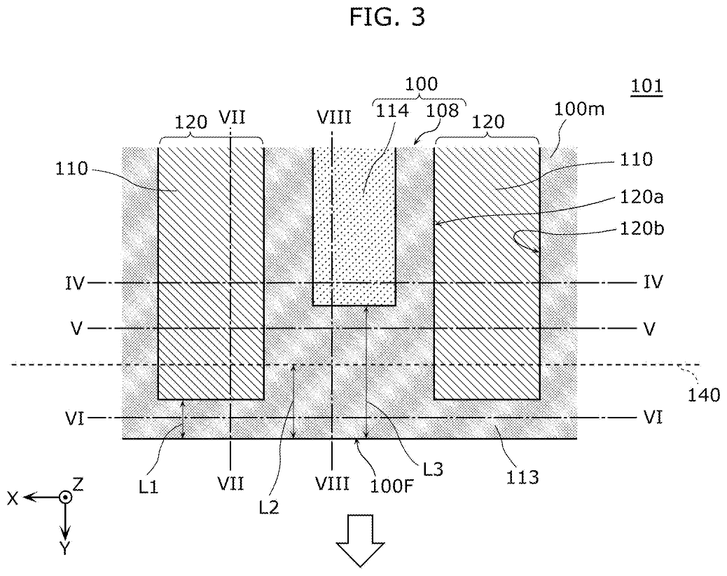

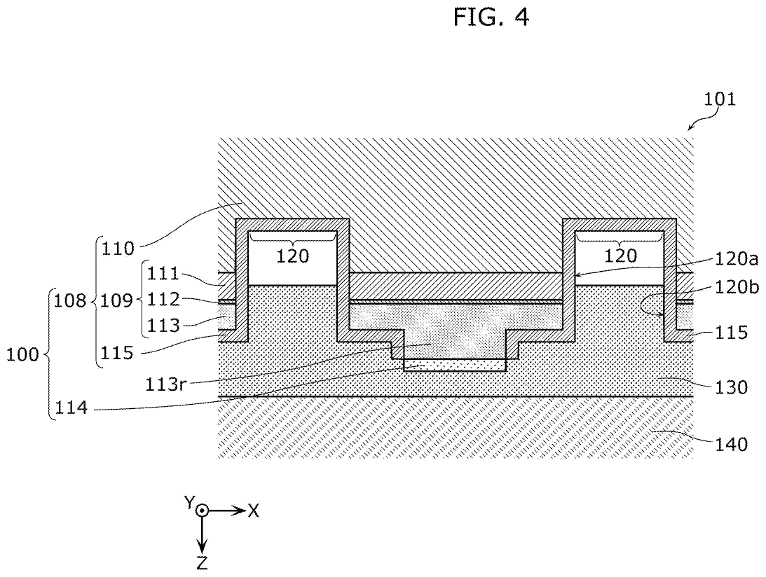

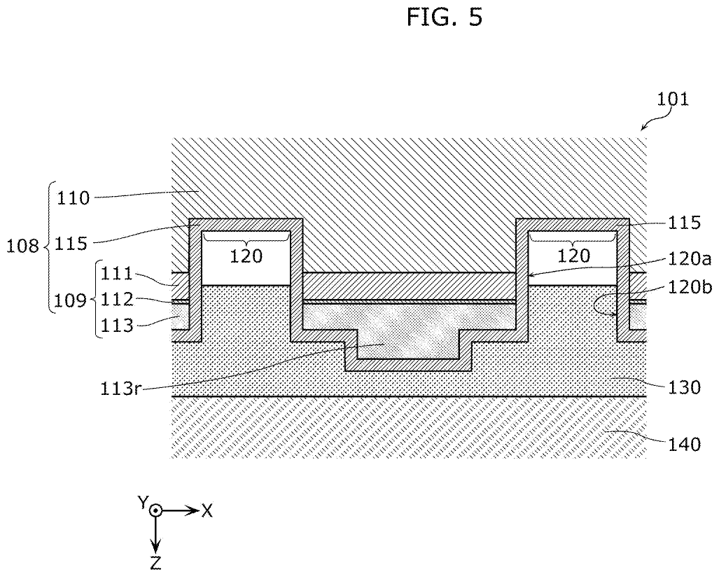

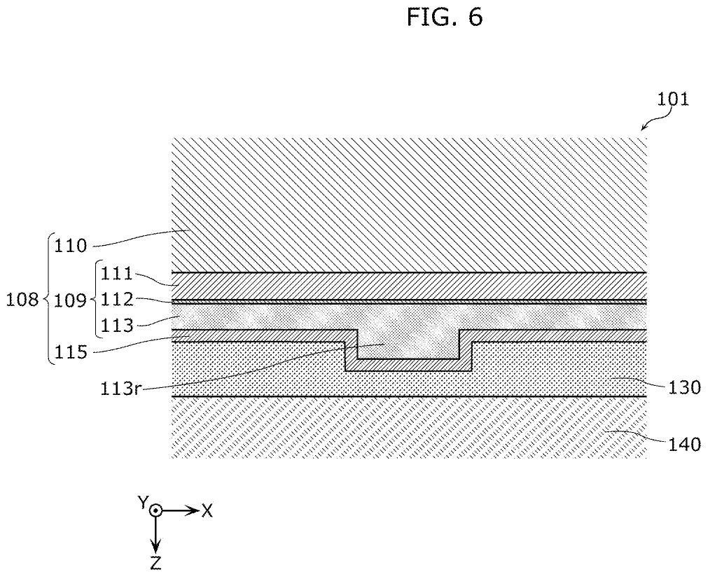

The overall configuration of the semiconductor light emitting device according to the present embodiment will first be described with reference to FIGS. 1 to 6. FIGS. 1 and 2 are respectively schematic perspective views showing the overall configurations of semiconductor light emitting element 100 and semiconductor light emitting device 101 according to the present embodiment. FIG. 3 is a schematic plan view showing a configuration in the vicinity of emission surface 100F of semiconductor light emitting device 101 according to the present embodiment. FIG. 3 shows a plan view in a position corresponding to the inside of dashed frame III in FIG. 1. In FIG. 3, a part of submount 140 is omitted so that the configuration of semiconductor light emitting element 100 is shown, and only the position of an end surface of submount 140 is indicated by a dashed line. FIGS. 4 to 6 are schematic cross-sectional views showing the configuration of semiconductor light emitting device 101 according to the present embodiment. FIGS. 4 to 6 respectively show cross sections taken along line IV-IV, line V-V, and line VI-VI in semiconductor light emitting device 101 shown in FIG. 3. In each of the figures, an X-axis, a Y-axis, and a Z-axis perpendicular to each other are shown.

As shown in FIG. 2, semiconductor light emitting device 101 according to the present embodiment includes: semiconductor light emitting element 100 that emits light; and submount 140 that includes mounting surface 140m on which semiconductor light emitting element 100 is mounted via bonding material 130 (see FIGS. 4 to 6). Semiconductor light emitting device 101 further includes bonding material 130 which bonds semiconductor light emitting element 100 and submount 140.

Submount 140 is a base on which semiconductor light emitting element 100 is mounted and which has high thermal conductivity, and has the function of dissipating heat generated in semiconductor light emitting element 100. Semiconductor light emitting element 100 is mounted on submount 140 via bonding material 130. In the present embodiment, submount 140 is formed of AlN, diamond, or the like, and is in the shape of a rectangular parallelepiped.

Although bonding material 130 is not particularly limited as long as bonding material 130 is a material capable of bonding semiconductor light emitting element 100 and submount 140, bonding material 130 is, for example, a solder containing AuSn or the like.

As shown in FIG. 1, semiconductor light emitting element 100 includes semiconductor multilayer structure 108 and mounting electrodes 114. In the present embodiment, semiconductor light emitting element 100 is a multi-emitter-type semiconductor laser array which emits a plurality of beams of laser light. The direction of emission of the light of semiconductor light emitting element 100 is a direction parallel to the direction of the Y-axis in each of the figures. In the present embodiment, the direction of emission of the light of semiconductor light emitting element 100 corresponds to the direction of resonance of the laser light.

Semiconductor multilayer structure 108 is an element in the shape of a rectangular parallelepiped, and includes, as shown in FIG. 2, opposite surface 100m opposite mounting surface 140m of submount 140 and emission surface 100F from which the light is emitted. Semiconductor multilayer structure 108 further includes back end surface 100R which is directed in a direction opposite to emission surface 100F. Opposite surface 100m is a surface perpendicular to the direction of the Z-axis in FIG. 2, and emission surface 100F is a surface perpendicular to the direction of the Y-axis in FIG. 2. In the present embodiment, light resonates between emission surface 100F and back end surface 100R. As shown in FIG. 3, emission surface 100F of semiconductor multilayer structure 108 is located outside of an end portion of mounting surface 140m of submount 140.

As shown in FIG. 1, one or more mounting electrodes 114 are arranged on opposite surface 100m of semiconductor multilayer structure 108, and one or more grooves 120 extending along mounting electrodes 114 in the direction of emission are formed therein. In the present embodiment, a plurality of grooves 120 are formed in semiconductor multilayer structure 108. As shown in FIG. 1, grooves 120 are arranged in a direction perpendicular to the direction of emission and parallel to opposite surface 100m. As shown in FIGS. 3 and 4, each of grooves 120 includes a pair of side walls 120a and 120b extending in the direction of emission. As shown in FIG. 3, first distance L1 between emission surface 100F of semiconductor light emitting element 100 and each of grooves 120 is greater than zero. In other words, grooves 120 are not formed in emission surface 100F. Here, more precisely, first distance L1 is defined as a distance between emission surface 100F and the position of each of grooves 120 closest to emission surface 100F (that is, the position closest to emission surface 100F). First distance L1 is less than second distance L2 between emission surface 100F and mounting surface 140m. Action and effects caused by a relationship between first distance L1 and second distance L2 will be described later.

For example, a wet etching method, a dry etching method, or the like is used, and thus grooves 120 are formed by etching crystal growth layer 109. In the present embodiment, a part of substrate 110 is also etched.

As shown in FIGS. 4 to 6, semiconductor multilayer structure 108 includes substrate 110, crystal growth layer 109, and insulating layer 115.

Substrate 110 is the base of semiconductor light emitting element 100. In the present embodiment, substrate 110 is an n-type GaN substrate having a thickness of 80 μm.

Crystal growth layer 109 is a semiconductor layer which is formed by crystal growth on a main surface of substrate 110.

Crystal growth layer 109 includes first semiconductor layer 111, light emitting layer 112, and second semiconductor layer 113. The layers of crystal growth layer 109 are formed, for example, by metal organic chemical vapor deposition (MOCVD) or the like.

First semiconductor layer 111 is a semiconductor layer of a first conductivity type arranged above substrate 110. In the present embodiment, the first conductivity type is n-type, and first semiconductor layer 111 includes an n-type clad layer of n-Al_{0.03}Ga_{0.97}N having a thickness of 3 μm. First semiconductor layer 111 may include a layer other than the n-type clad layer. For example, first semiconductor layer 111 may include a buffer layer or the like arranged between substrate 110 and the n-type clad layer.

Light emitting layer 112 is a layer arranged above first semiconductor layer 111. In the present embodiment, light emitting layer 112 includes a quantum well active layer in which a well layer of In_{0.06}Ga_{0.94}N having a thickness of 5 nm and a barrier layer of GaN having a thickness of 10 nm are alternately stacked, and includes two well layers. Light emitting layer 112 may include a layer other than the quantum well active layer. For example, light emitting layer 112 may include a light guide layer or the like.

Second semiconductor layer 113 is a semiconductor layer of a second conductivity type different from the first conductivity type arranged above light emitting layer 112. In the present embodiment, the second conductivity type is p-type, and second semiconductor layer 113 includes a p-type clad layer of a superlattice layer which has a thickness of 6 μm and in which one hundred layers of p-Al_{0.06}Ga_{0.94}N each having a thickness of 3 nm and one hundred layers of GaN each having a thickness of 3 nm are alternately stacked. Second semiconductor layer 113 may include a layer other than the p-type clad layer. For example, second semiconductor layer 113 may include a p-type contact layer arranged between the p-type clad layer and mounting electrode 114. As shown in FIGS. 4 to 6, in second semiconductor layer 113, ridge portion 113r for confining light and current is formed. For example, a dry etching method is used, and thus ridge portion 113r is formed by etching second semiconductor layer 113.

Insulating layer 115 is a layer arranged above second semiconductor layer 113 and formed of an insulating material. In insulating layer 115, an opening portion is formed, and mounting electrode 114 is arranged inside the opening portion. The opening portion is formed in a part of insulating layer 115 on ridge portion 113r. The front layer of groove 120 is also formed by insulating layer 115. In the present embodiment, insulating layer 115 is an SiO₂ layer having a thickness of 300 nm. In FIG. 3, insulating layer 115 is omitted. Insulating layer 115 is formed, for example, by a plasma CVD method.

Mounting electrode 114 is an electrode which is arranged on opposite surface 100m of semiconductor multilayer structure 108 and extends in the direction of emission of the light. In the present embodiment, as shown in FIG. 1, semiconductor light emitting element 100 includes a plurality of mounting electrodes 114. Mounting electrode 114 is in a rectangular shape in which its longitudinal direction is the direction of emission of the light. Mounting electrode 114 is a stacking film which is arranged above second semiconductor layer 113 and in which Pd and Pt are sequentially stacked in layers from the side of second semiconductor layer 113. Mounting electrode 114 is not formed in the vicinity of emission surface 100F of semiconductor multilayer structure 108. In other words, between mounting electrode 114 and emission surface 100F, a non-injection region into which current is not injected is formed. In this way, current is not supplied to a part in the vicinity of emission surface 100F which is the hottest part of semiconductor light emitting element 100, and thus it is possible to suppress the temperature in the vicinity of emission surface 100F. Hence, it is possible to suppress the occurrence of a COD in the vicinity of emission surface 100F. In the present embodiment, mounting electrode 114 arranged above second semiconductor layer 113 is arranged opposite mounting surface 114m of submount 140. In other words, semiconductor light emitting element 100 is junction-down mounted on submount 140. In this way, as compared with a case where semiconductor light emitting element 100 is junction-up mounted, light emitting layer 112 which generates a large amount of heat can be arranged close to submount 140, and thus it is possible to enhance the heat dissipation properties of semiconductor light emitting device 101.

For the arrangement of mounting electrode 114, as shown in FIG. 3, third distance L3 between emission surface 100F and mounting electrode 114 is greater than zero. Second distance L2 between emission surface 100F and mounting surface 140m of submount 140 is less than third distance L3 between emission surface 100F and mounting electrode 114. Action and effects caused by a relationship between second distance L2 and third distance L3 will be described later.

As shown in FIG. 3, in plan view of opposite surface 100m of semiconductor light emitting element 100, mounting electrode 114 is arranged between two adjacent grooves 120. In the present embodiment, as shown in FIG. 4, mounting electrode 114 is arranged on ridge portion 113r. In this way, current is supplied to a part of light emitting layer 112 located below mounting electrode 114. Hence, light is generated in a part of light emitting layer 112 opposite mounting electrode 114 (that is, a part located below ridge portion 113r).

Although not shown in the figure, in semiconductor light emitting element 100, a back surface electrode is formed on a main surface on the back side of the main surface where crystal growth layer 109 of substrate 110 is formed. The back surface electrode is, for example, a stacking film in which Ti, Pt, and Au are sequentially formed from substrate 110.

Mounting electrodes 114 and the back surface electrode in the present embodiment are formed, for example, by a vacuum deposition method or the like.

### [1-2. Action and Effects]

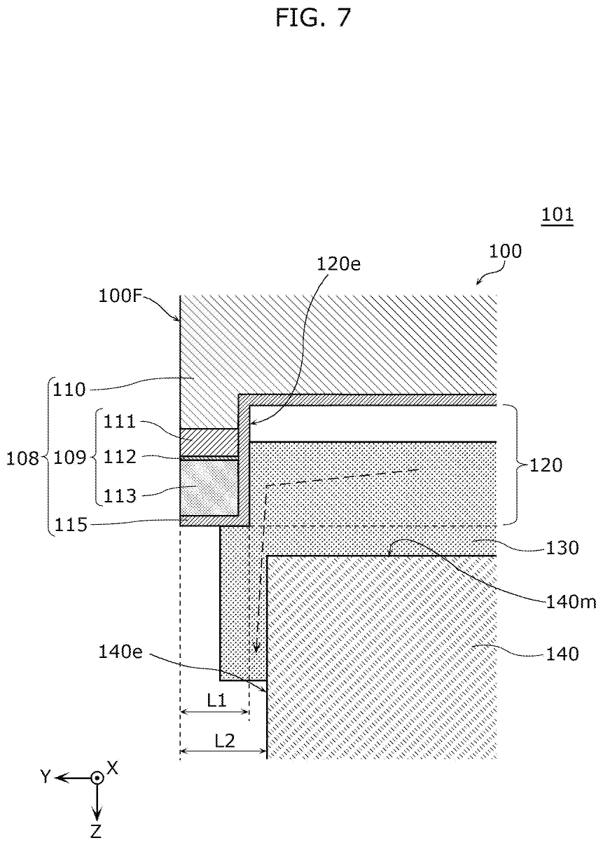

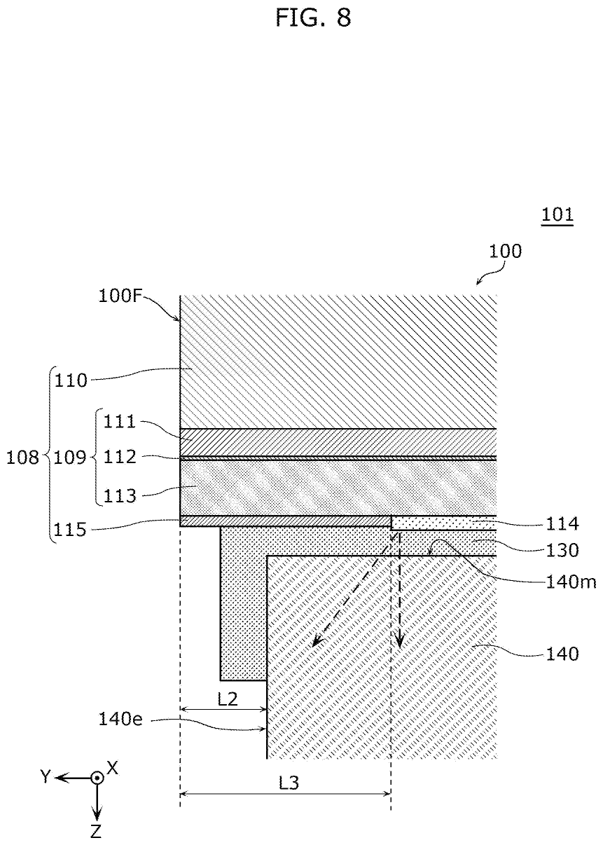

The action and effects of semiconductor light emitting device 101 according to the present embodiment will then be described with reference to FIGS. 7 and 8. FIGS. 7 and 8 are schematic cross-sectional views illustrating the action of semiconductor light emitting device 101 according to the present embodiment. FIGS. 7 and 8 respectively show cross sections taken along line VII-VII and line VIII-VIII in semiconductor light emitting device 101 shown in FIG. 3.

In order to mount semiconductor light emitting element 100 on submount 140, bonding material 130 arranged between submount 140 and semiconductor light emitting element 100 is melted by heating. When semiconductor light emitting element 100 is mounted on submount 140, semiconductor light emitting element 100 is pressed on bonding material 130 on submount 140. In this way, a part of bonding material 130 arranged between submount 140 and mounting electrode 114 shown in FIG. 8 is pressed out from between submount 140 and mounting electrode 114. Since in the present embodiment, grooves 120 are formed along mounting electrodes 114 in semiconductor light emitting element 100, as shown in FIG. 7, bonding material 130 which has been pressed out flows into groove 120. Hence, it is possible to reduce the amount of bonding material 130 which flows out from between emission surface 100F of semiconductor light emitting element 100 and submount 140.

It is likely that a part of bonding material 130 which has flowed into groove 120 flows out from between emission surface 100F of semiconductor light emitting element 100 and submount 140. In the present embodiment, as shown in FIG. 7, first distance L1 between emission surface 100F and groove 120 is less than second distance L2 between emission surface 100F and mounting surface 140m of submount 140. In other words, side wall 120e of groove 120 which is directed in the direction opposite to emission surface 100F is located outside of end surface 140e of submount 140. Hence, bonding material 130 flowing out from between semiconductor light emitting element 100 and submount 140 via groove 120 is guided to flow along side wall 120e of groove 120 which is substantially parallel to emission surface 100F. In other words, bonding material 130 is guided to flow along end surface 140e located on the end portion of mounting surface 140m of submount 140. Hence, it is possible to suppress the protrusion of bonding material 130 in a direction perpendicular to emission surface 100F in the vicinity of emission surface 100F.

As shown in FIG. 8, mounting electrode 114 in the vicinity of emission surface 100F is bonded to submount 140. Here, since as described above, the protrusion of bonding material 130 in the vicinity of emission surface 100F is suppressed, as in the submount disclosed in PTL 1, a material which has low thermal conductivity does not need to be arranged in a part of submount 140 in the vicinity of emission surface 100F. Hence, in the present embodiment, the heat dissipation properties of semiconductor light emitting device 101 in the vicinity of emission surface 100F are not degraded. Furthermore, in the present embodiment, as shown in FIG. 8, second distance L2 is less than third distance L3 between emission surface 100F and mounting electrode 114. In this way, heat generated in the vicinity of the end portion of mounting electrode 114 of semiconductor light emitting element 100 close to emission surface 100F is dissipated not only in a direction perpendicular to mounting surface 140m (that is, downward of mounting electrode 114 in FIG. 8) but also in a direction toward end surface 140e of submount 140, that is, in a direction inclined with respect to mounting surface 140m (see dashed arrows in FIG. 8). On the other hand, when second distance L2 is greater than or equal to third distance L3, that is, when mounting electrode 114 is arranged up to the end portion of mounting surface 140m of submount 140, heat generated in the vicinity of the end portion of mounting electrode 114 close to emission surface 100F is dissipated only in the direction perpendicular to mounting surface 140m. Hence, second distance L2 is less than third distance L3, and thus as compared with a case where second distance L2 is greater than or equal to third distance L3, the heat dissipation properties of semiconductor light emitting device 101 can be enhanced.

As described above, in semiconductor light emitting device 101 according to the present embodiment, satisfactory heat dissipation properties are provided, and thus it is possible to suppress the protrusion of bonding material 130 in the vicinity of emission surface 100F of semiconductor light emitting element 100. When as in the present embodiment, semiconductor light emitting element 100 is a multi-emitter type, though the amount of heat generated in semiconductor light emitting element 100 is further increased, the heat dissipation properties caused by submount 140 are satisfactory, with the result that it is possible to suppress the occurrence of a COD.

### Embodiment 2

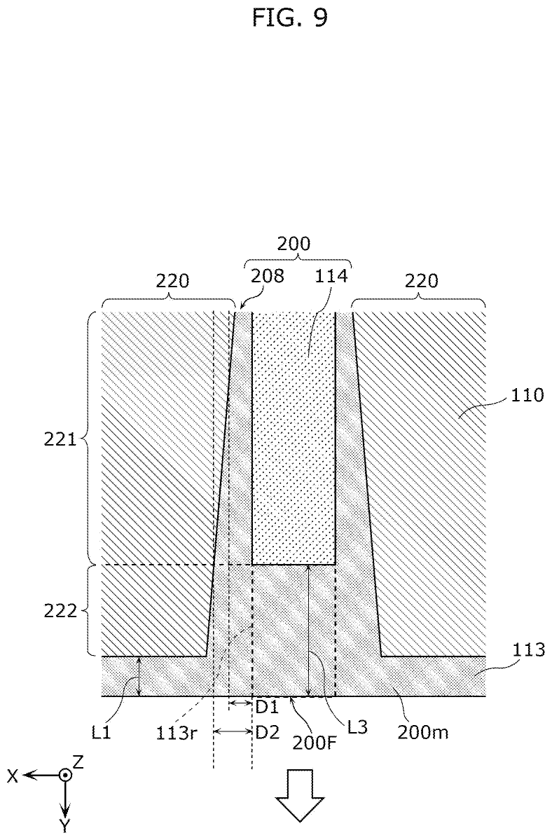

A semiconductor light emitting device according to Embodiment 2 will be described. The semiconductor light emitting device according to the present embodiment differs from semiconductor light emitting device 101 according to Embodiment 1 in the shape of grooves formed in a semiconductor light emitting element. The semiconductor light emitting device according to the present embodiment will be described below mainly on differences from semiconductor light emitting device 101 according to Embodiment 1 with reference to FIG. 9.

FIG. 9 is a schematic plan view showing a configuration in the vicinity of emission surface 200F of semiconductor light emitting element 200 included in the semiconductor light emitting device according to the present embodiment. FIG. 9 shows a plan view when opposite surface 200m of semiconductor light emitting element 200 is seen in plan view.

The semiconductor light emitting device according to the present embodiment includes semiconductor light emitting element 200 and submount 140.

Semiconductor light emitting element 200 according to the present embodiment includes semiconductor multilayer structure 208 and one or more mounting electrodes 114. In semiconductor multilayer structure 208 of the present embodiment, one or more mounting electrodes 114 are arranged, and one or more grooves 220 extending along mounting electrodes 114 in the direction of emission are formed. Semiconductor light emitting element 200 in the present embodiment differs from semiconductor light emitting element 100 in Embodiment 1 in the shape of grooves 220 and is the same as semiconductor light emitting element 100 in the other configurations.

As shown in FIG. 9, average distance D1 in a direction perpendicular to the direction of emission (and the stacking direction of semiconductor multilayer structure 208) between mounting electrode 114 and first part 221 of groove 220 adjacent to mounting electrode 114 in the direction perpendicular to the direction of emission (and the stacking direction of semiconductor multilayer structure 208) (that is, the direction of the X-axis in FIG. 9) is less than average distance D2 in the direction perpendicular to the direction of emission (and the stacking direction of semiconductor multilayer structure 208) between mounting electrode 114 and second part 222 of groove 220 located closer to the emission surface than mounting electrode 114. In other words, average distance D1 between first part 221 of groove 220 adjacent to mounting electrode 114 in the direction of the X-axis and ridge portion 113r of second semiconductor layer 113 is less than average distance D2 between second part 222 of groove 220 located closer to the emission surface than mounting electrode 114 and ridge portion 113r.

The action and effects of semiconductor light emitting element 200 in the present embodiment will be described below. The inventor has found that grooves 220 are formed to increase distortion applied to light emitting layer 112 arranged in the vicinity thereof and thus a bandgap in light emitting layer 112 is decreased. Hence, as an average distance between light emitting layer 112 and groove 220 is smaller, the bandgap in light emitting layer 112 is decreased. In the present embodiment, semiconductor light emitting element 200 has the configuration described above. In this way, light emitting layer 112 arranged between mounting electrode 114 and emission surface 200F, that is, light emitting layer 112 in a non-injection region is greater in average bandgap than light emitting layer 112 in a part opposite mounting electrode 114, that is, light emitting layer 112 in an injection region. Hence, it is possible to reduce light absorption caused by the light emitting layer in the non-injection region in the vicinity of emission surface 200F, and thus the amount of heat generated in the non-injection region is decreased. Therefore, in semiconductor light emitting element 200 of the present embodiment, the occurrence of a COD in the non-injection region can be suppressed.

Although in the example shown in FIG. 9, the shape of a side surface of groove 220 close to mounting electrode 114 in plan view is linear, the shape may be curved.

### Embodiment 3

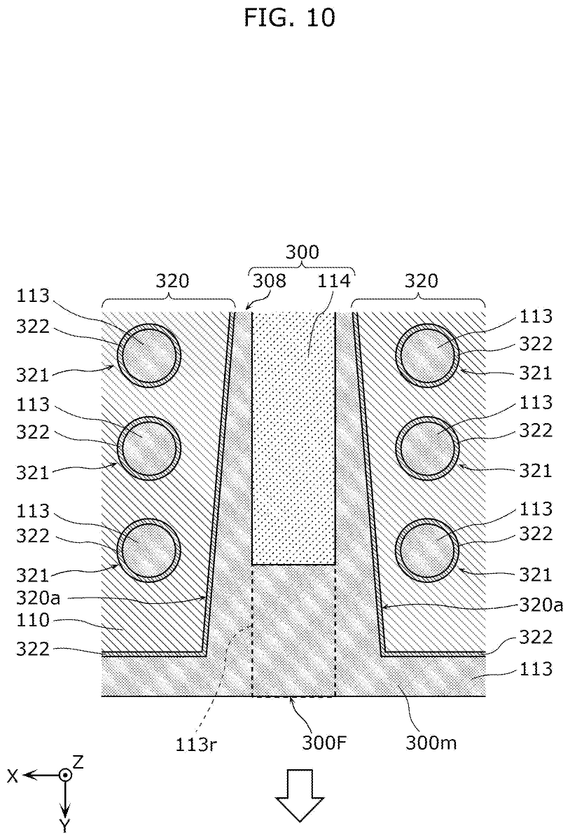

A semiconductor light emitting device according to Embodiment 3 will be described. The semiconductor light emitting device according to the present embodiment differs from the semiconductor light emitting device according to Embodiment 2 in the internal configuration of grooves formed in a semiconductor light emitting element. The semiconductor light emitting device according to the present embodiment will be described below mainly on differences from the semiconductor light emitting device according to Embodiment 2 with reference to FIG. 10.

FIG. 10 is a schematic plan view showing a configuration in the vicinity of emission surface 300F of semiconductor light emitting element 300 included in the semiconductor light emitting device according to the present embodiment. FIG. 10 shows a plan view when opposite surface 300m of semiconductor light emitting element 300 opposite submount 140 is seen in plan view.

The semiconductor light emitting device according to the present embodiment includes semiconductor light emitting element 300 and submount 140.

Semiconductor light emitting element 300 in the present embodiment includes semiconductor multilayer structure 308 and one or more mounting electrodes 114. In semiconductor multilayer structure 308 of the present embodiment, one or more mounting electrodes 114 are arranged, and one or more grooves 320 extending along mounting electrodes 114 in the direction of emission are formed. Semiconductor light emitting element 300 in the present embodiment differs from semiconductor light emitting element 200 in Embodiment 2 in the internal configuration of grooves 320 and is the same as semiconductor light emitting element 200 in the other configurations.

In the present embodiment, side wall 320a of groove 320 includes Au layer 322 which has higher wettability to bonding material 130 than semiconductor multilayer structure 308. Hence, the wettability to bonding material 130 in side walls 320a of grooves 320 can be enhanced, and thus it is possible to enhance an effect of guiding bonding material 130 into grooves 320 along side walls 320a.

In the present embodiment, in groove 320, one or more projecting portions 321 are formed. In an example shown in FIG. 10, each of projecting portions 321 is a cylindrical part which is provided to stand on the bottom surface of groove 320. For example, projecting portions 321 may be formed by being left as parts which are not etched inside groove 320 when groove 320 is formed by etching or the like. In the example shown in FIG. 10, projecting portions 321 are formed by being left as parts which are not removed when a part of second semiconductor layer 113 in semiconductor multilayer structure 308 or the like is etched. Projecting portions 321 as described above are formed inside groove 320, and thus a contact area between bonding material 130 and the inside of groove 320 can be increased. Hence, it is possible to further enhance the effect of guiding bonding material 130 into groove 320.

Furthermore, as shown in FIG. 10, projecting portion 321 may include Au layer 322 as with side wall 320a. In this way, it is possible to further enhance the effect of guiding bonding material 130 into groove 320. Although not shown in FIG. 10, an insulating layer formed of SiO₂ or the like is arranged between Au layer 322 and a semiconductor such as second semiconductor layer 113.

The bottom surface of groove 320 may also include an AU layer. In this way, it is possible to further enhance the effect of guiding bonding material 130 into groove 320.

Although in the present embodiment, Au layer 322 is used as a layer which has good wettability to bonding material 130, a metal layer, such as an Ag layer, a Sn layer, a Ni layer, or a Pd layer, other than Au layer 322 may be used.

### Embodiment 4

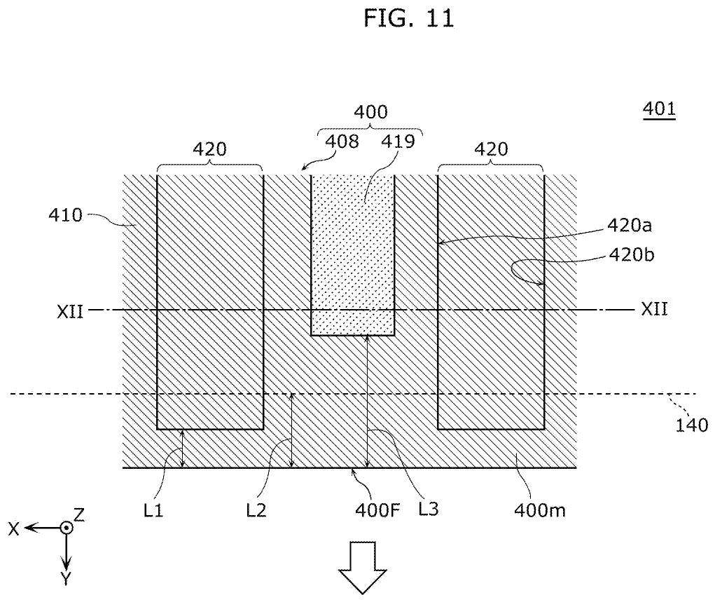

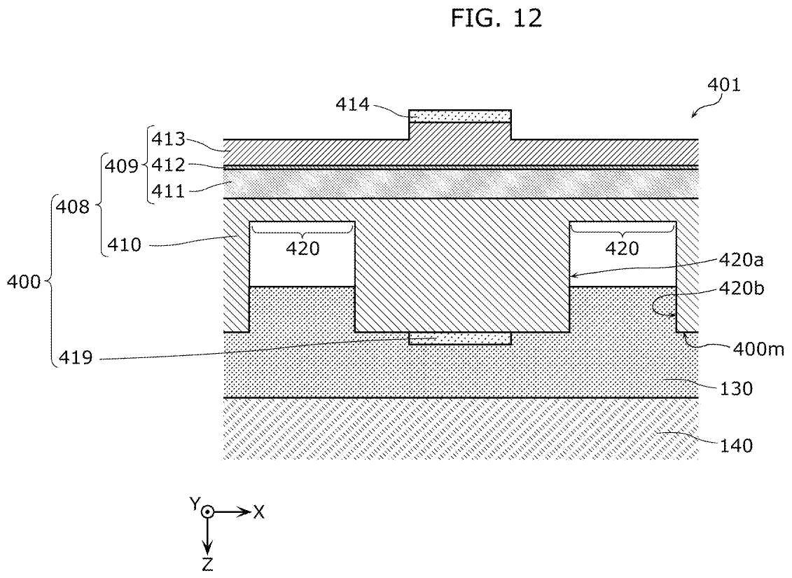

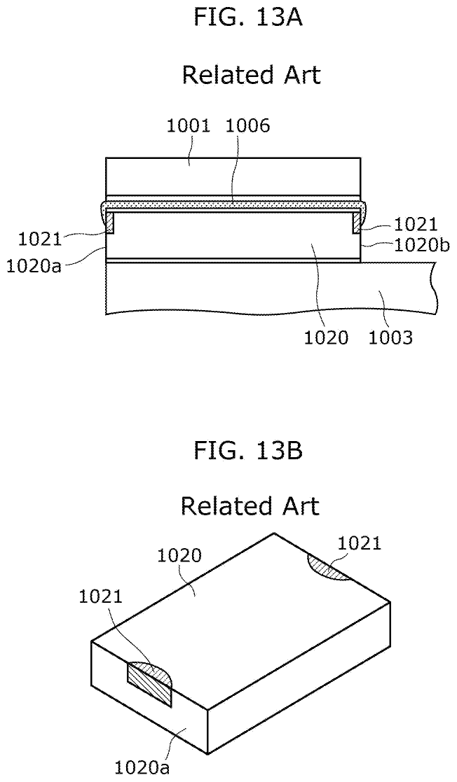

A semiconductor light emitting device according to Embodiment 4 will be described. The semiconductor light emitting device according to the present embodiment differs from semiconductor light emitting device 101 according to Embodiment 1 in that grooves are formed from the side of the substrate of a semiconductor light emitting element. The semiconductor light emitting device according to the present embodiment will be described below mainly on differences from semiconductor light emitting device 101 according to Embodiment 1 with reference to FIGS. 11 and 12.

FIGS. 11 and 12 are respectively a schematic plan view and a schematic cross-sectional view showing a configuration in the vicinity of emission surface 400F of semiconductor light emitting device 401 according to the present embodiment. In FIG. 11, a part of submount 140 is omitted so that the configuration of semiconductor light emitting element 400 included in semiconductor light emitting device 401 is shown, and only the position of an end surface of submount 140 is indicated by a dashed line. FIG. 12 shows a cross section taken along line XII-XII in semiconductor light emitting device 401 shown in FIG. 11.

As shown in FIGS. 11 and 12, semiconductor light emitting device 401 according to the present embodiment includes semiconductor light emitting element 400 and submount 140. As shown in FIG. 12, semiconductor light emitting device 401 further includes bonding material 130.

As shown in FIG. 12, semiconductor light emitting element 400 in the present embodiment includes semiconductor multilayer structure 408, one or more mounting electrodes 419, and one or more back surface electrodes 414. Semiconductor multilayer structure 408 includes substrate 410 and crystal growth layer 409. Crystal growth layer 409 includes first semiconductor layer 411, light emitting layer 412, and second semiconductor layer 413. Substrate 410, first semiconductor layer 411, light emitting layer 412, and second semiconductor layer 413 respectively have the same material and thickness as substrate 110, first semiconductor layer 411, light emitting layer 412, and second semiconductor layer 413 in semiconductor light emitting element 100 of Embodiment 1. Back surface electrode 414 is arranged above second semiconductor layer 413. Back surface electrode 414 has the same configuration as mounting electrode 114 in Embodiment 1.

In the present embodiment, as shown in FIG. 12, opposite surface 400m of semiconductor multilayer structure 408 opposite submount 140 is a main surface on the back side of the main surface of substrate 410 on which crystal growth layer 409 is stacked. On opposite surface 400m, one or more mounting electrodes 419 are arranged, and one or more grooves 420 extending along mounting electrodes 419 in the direction of emission are formed. In the present embodiment, semiconductor light emitting element 400 includes a plurality of mounting electrodes 419, and in opposite surface 400m, a plurality of grooves 420 are formed. As shown in FIGS. 11 and 12, each of grooves 420 includes a pair of side walls 420a and 420b extending in the direction of emission.

As shown in FIG. 11, first distance L1 between emission surface 400F of semiconductor light emitting element 400 and each of grooves 420 is greater than zero. In other words, grooves 420 are not formed in emission surface 400F. First distance L1 is less than second distance L2 between emission surface 400F and mounting surface 140m. Since as described above, in semiconductor light emitting element 400, grooves 420 are formed along mounting electrodes 419, as in semiconductor light emitting device 101 according to Embodiment 1, bonding material 130 which is pressed out at the time of mounting flows into grooves 420. Hence, it is possible to reduce the amount of bonding material 130 flowing out from between emission surface 400F of semiconductor light emitting element 400 and submount 140.

For the arrangement of mounting electrode 419, as shown in FIG. 11, third distance L3 between emission surface 400F and mounting electrode 419 is greater than zero. Second distance L2 between emission surface 400F and mounting surface 140m of submount 140 is less than third distance L3 between emission surface 400F and mounting electrode 419. In this way, as in semiconductor light emitting device 101 according to Embodiment 1, the heat dissipation properties of semiconductor light emitting device 401 can be enhanced.

### (Variations and the Like)

Although the semiconductor light emitting device according to the present disclosure has been described above based on the embodiments, the present disclosure is not limited to the embodiments described above.

For example, although in the embodiments described above, the examples where the semiconductor light emitting element is a semiconductor laser element are described, the semiconductor light emitting element is not limited to the semiconductor laser element. For example, the semiconductor light emitting element may be a super luminescent diode.

Although in the embodiments described above, the first conductivity type is n-type, the first conductivity type may be n-type.

Although in the embodiments described above, the semiconductor light emitting element is a multi-emitter type which includes a plurality of mounting electrodes, the semiconductor light emitting element may be a single-emitter type which includes a single mounting electrode. In other words, it is sufficient that the semiconductor light emitting element includes one or more mounting electrodes.

Although in the embodiments described above, a plurality of grooves are formed in the semiconductor light emitting element, a single groove may be formed in the semiconductor light emitting element. In other words, it is sufficient that one or more grooves are formed in the semiconductor light emitting element.

Although in the embodiments described above, the configuration in the vicinity of the emission surface of the semiconductor light emitting element is described, the same configuration as in the vicinity of the emission surface may be provided in the vicinity of the back end surface of the semiconductor light emitting element. In other words, a first distance between the back end surface and one or more grooves may be greater than zero, and may be less than a second distance between the back end surface and the mounting surface of the submount. The second distance may be less than a third distance between the back end surface and one or more mounting electrodes. In this way, the same effects as in the embodiments described above are achieved.

Although in Embodiments 1 to 3 described above, a plurality of grooves are formed part way through substrate 110 from the front surface of second semiconductor layer 113, the configuration of the grooves is not limited to this configuration. The grooves do not need to be formed from the front surface of second semiconductor layer 113 to substrate 110, and may be, for example, formed part way through first semiconductor layer 111 from the front surface of second semiconductor layer 113.

Although in Embodiment 2, one mounting electrode 114 and grooves 220 adjacent to mounting electrode 114 are described, semiconductor light emitting element 200 may include single mounting electrode 114 or may include a plurality of mounting electrodes 114. When semiconductor light emitting element 200 includes a plurality of mounting electrodes 114, only one mounting electrode 114 and grooves 220 adjacent to mounting electrode 114 may have the configuration corresponding to Embodiment 2 or other mounting electrodes 114 and grooves 220 adjacent thereto may also have the configuration corresponding to Embodiment 2. In other words, one or more mounting electrodes may include a first mounting electrode, one or more grooves may include a first groove adjacent to the first mounting electrode, and an average distance in a direction perpendicular to the direction of emission between the first mounting electrode and a part of the first groove adjacent to the first mounting electrode in the direction perpendicular to the direction of emission may be less than an average distance in the direction perpendicular to the direction of emission between the first mounting electrode and a part of the first groove located closer to the emission surface than the first mounting electrode.

In Embodiment 4 described above, an insulating layer may be formed in a region of opposite surface 400m of semiconductor multilayer structure 408 where mounting electrodes 419 are not formed.

Embodiments obtained by performing, on the embodiments described above, various variations conceived by a person skilled in the art and embodiments realized by arbitrarily combining constituent elements and functions in the embodiments described above without departing from the spirit of the present disclosure are also included in the present disclosure.

### INDUSTRIAL APPLICABILITY

For example, the semiconductor light emitting element of the present disclosure can be applied as light sources having a high output and high efficiency to processors, projectors, and the like.

1. A semiconductor light emitting device comprising:
a semiconductor light emitting element that emits light; and
a submount that includes a mounting surface on which the semiconductor light emitting element is mounted via a bonding material,
wherein the semiconductor light emitting element includes:
a semiconductor multilayer structure that includes: an opposite surface opposite the mounting surface; and an emission surface which is located at an end portion of the opposite surface and emits the light; and
one or more mounting electrodes that are arranged on the opposite surface of the semiconductor multilayer structure and extend in a direction of emission of the light,
the emission surface is located outside of an end portion of the mounting surface,
one or more grooves are formed in the opposite surface of the semiconductor multilayer structure to extend along the one or more mounting electrodes in the direction of emission, and
a first distance between the emission surface and the one or more grooves is greater than zero and less than a second distance between the emission surface and the mounting surface.

2. The semiconductor light emitting device according to claim 1,
wherein the second distance is less than a third distance between the emission surface and the one or more mounting electrodes.

3. The semiconductor light emitting device according to claim 1,
wherein the semiconductor multilayer structure includes:
a substrate;
a first semiconductor layer of a first conductivity type arranged above the substrate;
a light emitting layer arranged above the first semiconductor layer; and
a second semiconductor layer of a second conductivity type different from the first conductivity type, the second semiconductor layer being arranged above the light emitting layer, and
the one or more mounting electrodes are arranged above the second semiconductor layer.

4. The semiconductor light emitting device according to claim 3,
wherein the one or more mounting electrodes include a first mounting electrode,
the one or more grooves include a first groove adjacent to the first mounting electrode, and
an average distance in a direction perpendicular to the direction of emission between the first mounting electrode and a part of the first groove adjacent to the first mounting electrode in the direction perpendicular to the direction of emission is less than an average distance in the direction perpendicular to the direction of emission between the first mounting electrode and a part of the first groove located closer to the emission surface than the first mounting electrode.

5. The semiconductor light emitting device according to claim 1,
wherein a side wall of each of the one or more grooves includes a layer that has higher wettability to the bonding material than the semiconductor multilayer structure.

6. The semiconductor light emitting device according to claim 5,
wherein the side wall of each of the one or more grooves includes an Au layer.

7. The semiconductor light emitting device according to claim 1,
wherein in each of the one or more grooves, one or more projecting portions are formed.

8. The semiconductor light emitting device according to claim 1,
wherein the one or more mounting electrodes comprise a plurality of mounting electrodes, and
the one or more grooves comprise a plurality of grooves.
